(19) United States
(12) Patent Application Publication
(10) Pub. No.: US 2025/0239441 A1
(43) Pub. Date: Jul. 24, 2025

(54) PROCESS STAGE TRANSITION DETECTION FOR PLASMA SYSTEMS

(71) Applicant: Applied Materials, Inc., Santa Clara, CA (US)

(72) Inventors: Bharati Neelamraju, Sunnyvale, CA (US); Prashant Kumar Kulshreshtha, San Jose, CA (US); Yuta Kageyama, Yokkaichi (JP); Takashi Kitagaki, Ashiya (JP)

(73) Assignee: Applied Materials, Inc., Santa Clara, CA (US)

(21) Appl. No.: 18/420,376

(22) Filed: Jan. 23, 2024

(51) Int. Cl. H01J 37/32; C23C 16/06; C23C 16/24; C23C 16/26

(52) U.S. Cl. CPC H01J 37/32935; C23C 16/06; C23C 16/24; C23C 16/26

(57) ABSTRACT

A goal of a gapfill deposition process may be to form a relatively flat overgrowth layer of gapfill material above a top of the pillars. The relatively flat overgrowth layer can be formed by automatically stopping the gapfill deposition process after detecting an end of a stage (e.g., a sidewall growth stage) of the gapfill process. A characteristic of the plasma, such as an impedance of the plasma may be monitored during the plasma process. Changes in the characteristic may be correlated with different stages in the process, such as different stages in the gapfill process. When the characteristic indicates, a stage in the gapfill process may be identified, and an action may be taken, such as stopping the gapfill process. This provides live monitoring of the gapfill based on plasma characteristics rather than on measurements taken after the gap fill process is complete.

### TECHNICAL FIELD

This disclosure generally describes plasma system fabrication processes. More specifically, this disclosure describes in-situ stage transition detection for plasma system fabrication processes.

### BACKGROUND

Integrated circuits are made possible by processes which produce intricately patterned material layers on substrate surfaces. Producing patterned material on a substrate requires controlled methods of formation and removal of exposed material. As device sizes continue to shrink, material formation may affect subsequent operations. For example, in gap filling operations a material may be formed or deposited to fill a trench or other features formed on a semiconductor substrate. Gap filling operations can involve multiple stages during a gapfill deposition process. For some devices, it may be necessary to detect transitions from one stage to another in order to effectively fabricate high quality devices and structures.

Thus, there is a need for improved systems and methods that can be used to produce high quality devices and structures. These and other needs are addressed by the present technology.

### SUMMARY

In some embodiments, a method may include measuring a characteristic of a plasma; monitoring the characteristic of the plasma during a process involving the plasma; detecting an end of a stage of the process based on a comparison of the measured characteristic to a reference value; and performing at least one action in response to detecting the end of the stage of the process.

In some embodiments, a system may include a plasma system configured to perform deposition processes or etching processes; at least one sensor configured to measure a characteristic of a plasma in the plasma system; and a controller with one or more processors and one or more memory devices comprising instructions that are executable by the processor for causing the processor to perform operations including monitoring the characteristic during a process involving the plasma. The operations may also include detecting an end of a stage of the process based on a comparison of the characteristic and a reference value; and performing at least one action in response to detecting the end of the stage of the process.

In some embodiments, one or more non-transitory computer-readable media may include instructions that, when executed by one or more processors, cause the one or more processors to perform operations including monitoring a measured characteristic of a plasma during a process involving the plasma; detecting an end of a stage of the process based on a comparison of the measured characteristic to a reference value; and performing at least one action in response to detecting the end of the stage of the process.

In any embodiments, any and/or all of the following features may be implemented in any combination and without limitation. The characteristic may include an impedance of the plasma, where the process is a plasma-enhanced chemical vapor deposition (PECVD) gapfill deposition process for a patterned sample, the stage of the process may include a sidewall pinch-off stage, and performing the at least one action may include automatically ending the process after a duration of time measured from the detection. The patterned sample may include a plurality of trenches, and at least one trench in the plurality of trenches may include a different dimension than a dimension of any other trench in the plurality of trenches. The gapfill deposition process may include a deposition of gapfill material comprising carbon, tungsten, or amorphous silicon. The reference value may be based on conditions associated with the process. The conditions associated with the process may include types of plasma gases, a flow rate of at least one plasma gas, a temperature, precursors involved in the process, at least one deposition rate, or at least one etch rate. A slope of the characteristic over time for a portion of the process may be measured, and at least one step in a sample patterning process may be altered based on the slope.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 shows a schematic cross-sectional view of an exemplary processing chamber according to some embodiments of the present technology.

FIG. 2 shows a schematic cross-sectional view of a patterned sample that can be incorporated in processes, according to some embodiments.

FIG. 3 shows schematics of cross-sectional views of a patterned sample during different portions of a gapfill deposition process, according to some embodiments.

FIG. 4 is a graph of a characteristic of a plasma during a gapfill deposition process, according to some embodiments.

FIG. 5 is a cross-sectional transmission electron microscope (TEM) image of a patterned sample with trenches partially filled with gapfill material, according to some embodiments.

FIG. 6 is a flow chart of an example of a process for detecting an end of a stage of a deposition process according to some aspects of the present disclosure.

FIG. 7 illustrates an exemplary computer system, in which various embodiments may be implemented.

### DETAILED DESCRIPTION

Certain aspects and examples of the present disclosure relate to stage transition detection for a fabrication process involving a plasma system. For example, the fabrication process can be a gapfill deposition process of a patterned sample that includes pillars and trenches. The pillars and trenches can include dimensions of varying sizes which can create challenges for optimizing aspects of the deposition process. A goal of the gapfill deposition process can be to form a relatively flat overgrowth layer of gapfill material above a top of the pillars. The relatively flat overgrowth layer can be formed by automatically stopping the gapfill deposition process after a duration of time passes after detecting an end of a stage (e.g., a sidewall growth stage) of the fabrication process. A characteristic of the plasma, such as an impedance of the plasma may be monitored during the plasma process. Changes in the characteristic may be correlated with different stages in the process, such as different stages in the gapfill process. When the characteristic indicates, a stage in the gapfill process may be identified, and an action may be taken, such as stopping the gapfill process. This provides an in situ monitoring of the gapfill based on plasma characteristics rather than intrusive measurements or measurements taken after the gap fill process is complete.

After describing general aspects of a chamber according to some embodiments of the present technology in which plasma processing operations discussed below may be performed, specific methodology may be discussed. It is to be understood that the present technology is not intended to be limited to the specific films, chambers or processes discussed, as the techniques described may be used to improve a number of film formation processes, and may be applicable to a variety of processing chambers and operations.

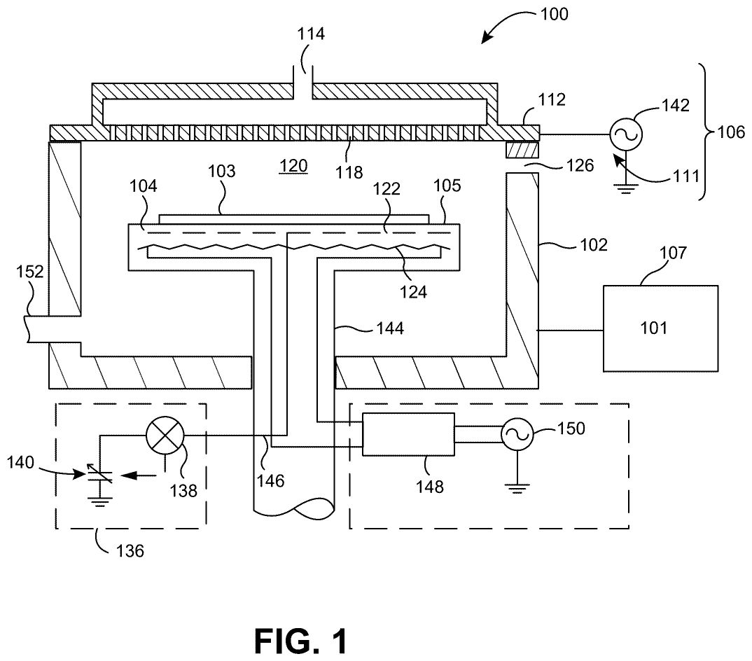

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, along a vertical axis, where a shaft 144 of the substrate support 104 may be located, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Upon energizing a plasma in the processing volume 120, a potential difference may be established between the plasma and the first electrode 122. The electronic controller 140 may then be used to adjust the flow properties of the ground paths represented by the tuning circuit 136. A set point may be delivered to the tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the tuning circuit 136 in a closed loop. A set point for current or voltage, depending on the type of sensor used, may be installed in each sensor, and the sensor may be provided with control software that determines an adjustment to the electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

Processing chamber 100 may be utilized in some embodiments of the present technology for processing methods that may include bottom-up deposition of materials for semiconductor structures. It is to be understood that the chamber described is not to be considered limiting, and any chamber that may be configured to perform operations as described may be similarly used.

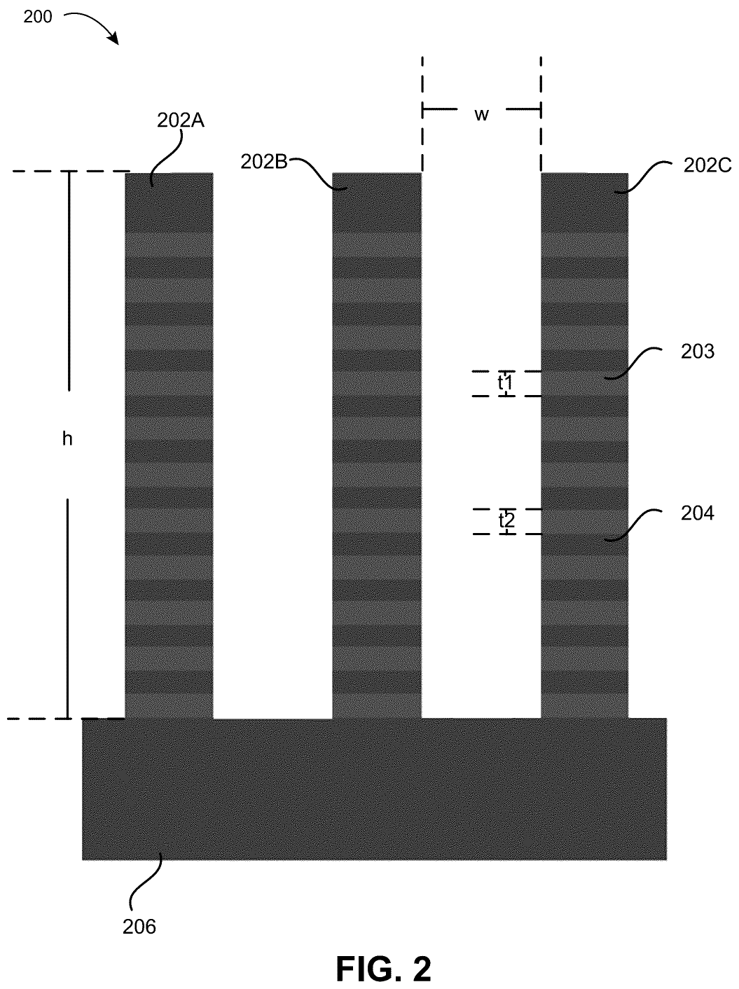

FIG. 2 shows a schematic cross-sectional view of a patterned sample 200 that can be incorporated in processes, according to some embodiments. The patterned sample 200 can include a substrate 206 and pillars such as pillar 202A, pillar 202B, and pillar 202C. Although three pillars are shown in FIG. 2, the patterned sample 200 can include any number of pillars. Each of the pillars can be formed from multiple alternating deposited layers, such as layer 203 or layer 204. Layer 203 and layer 204 can be deposited layers in a memory stack structure such as a NAND structure. For example, the layer 203 can be a deposited silicon oxide layer and the layer 204 can be a deposited silicon nitride layer. Although there are several alternating deposited layers shown in FIG. 2, for simplicity only layer 203 and layer 204 are labeled. The alternating deposited layers can have a layer thicknesses. For example, layer 203 can have a thickness, t1, and layer 204 can have a thickness, t2. In some examples, each of the alternating layers can have a same thickness (t1=t2).

For example, each of the alternating layers can have a thickness of about 50 nm. For example, each alternating layer can have a thickness of between about 5 nm and about 10 nm, between about 10 nm and about 15 nm, between about 15 nm and about 20 nm, between about 20 nm and about 25 nm, between about 25 nm and about 30 nm, between about 30 nm and about 35 nm, between about 35 nm and about 40 nm, between about 40 nm and about 45 nm, between about 45 nm and about 50 nm, between about 50 nm and about 55 nm, between about 55 nm and about 60 nm, between about 60 nm and about 65 nm, between about 65 nm and about 70 nm, between about 70 nm and about 75 nm, between about 75 nm and about 80 nm, between about 80 nm and about 85 nm, between about 85 nm and about 90 nm, between about 90 nm and about 95 nm, and/or between about 95 nm and about 100 nm. The thickness of each layer may also be any combination of these ranges (e.g., between about 50 nm and about 100 nm). The thickness of each layer may also be any specific value within these ranges (e.g., about 50 nm). Each alternating layer can have a different thickness. For example, the thickness of layer 203 can be different than the thickness of layer 204 (t1≠t2).

The multiple alternating deposited layers can be etched to form the pillars. An etch region between adjacent pillars can form a trench. Each trench can have a width, w, and a height, h. The trenches can be relatively deep trenches (e.g., h>>w). For example, the width of a trench can be about 100 nm. For example, each trench can have a width of between about 10 nm and about 30 nm, between about 30 nm and about 50 nm, between about 50 nm and about 70 nm, between about 70 nm and about 90 nm, between about 90 nm and about 110 nm, between about 110 nm and about 130 nm, between about 130 nm and about 150 nm, between about 150 nm and about 170 nm, between about 170 nm and about 190 nm, between about 190 nm and about 210 nm, between about 210 nm and about 230 nm, between about 230 nm and about 250 nm, between about 250 nm and about 270 nm, between about 270 nm and about 290 nm, between about 290 nm and about 310 nm, between about 310 nm and about 330 nm, and/or between about 330 nm and about 350 nm. The width of each trench may also be any combination of these ranges (e.g., between about 10 nm and about 350 nm). The width of each trench may also be any specific value within these ranges (e.g., about 150 nm).

The height of a trench can be about 10 microns. For example, each trench can have a height of between about 1 microns and about 3 microns, between about 3 microns and about 5 microns, between about 5 microns and about 7 microns, between about 7 microns and about 9 microns, between about 9 microns and about 11 microns, between about 11 microns and about 13 microns, between about 13 microns and about 15 microns, between about 15 microns and about 17 microns, between about 17 microns and about 19 microns, between about 19 microns and about 21 microns, between about 21 microns and about 23 microns, between about 23 microns and about 25 microns, between about 25 microns and about 27 microns, between about 27 microns and about 29 microns, between about 29 microns and about 31 microns, between about 31 microns and about 33 microns, and/or between about 33 microns and about 35 microns. The height of each trench may also be any combination of these ranges (e.g., between about 30 microns and about 35 microns). The height of each trench may also be any specific value within these ranges (e.g., about 150 microns). In some examples, the height of each trench can be designed to be a multiplicative factor of the width of each trench (e.g., h=50*w, h=100*w, etc.).

The height h, the width w, or both can have different values in different regions of the patterned sample 200. For example, the patterned sample 200 can be divided into four quadrants. In a first quadrant, a first subgroup of pillars can have widths of 10 nm and heights of 5 microns. In a second quadrant, a second subgroup of pillars can have widths of 50 nm and heights of 25 microns. A third quadrant can include a third subgroup of pillars having widths of 20 nm and heights of 10 microns. In a fourth quadrant, a fourth subgroup of pillars can have widths of 24 nm and heights of 10 microns.

The patterned sample 200 can be incorporated in a process, such as a deposition process. For example, the patterned sample 200 can be placed in a process chamber such as process chamber 100 from FIG. 1 and trenches of the patterned sample 200 can be filled by a plugfill material during a plasma-enhanced chemical vapor deposition PECVD process. During the PECVD process, beginnings and ends of stages of the PECVD process can be detected by monitoring changes in characteristics (e.g., impedance, etc.) of the plasma over time.

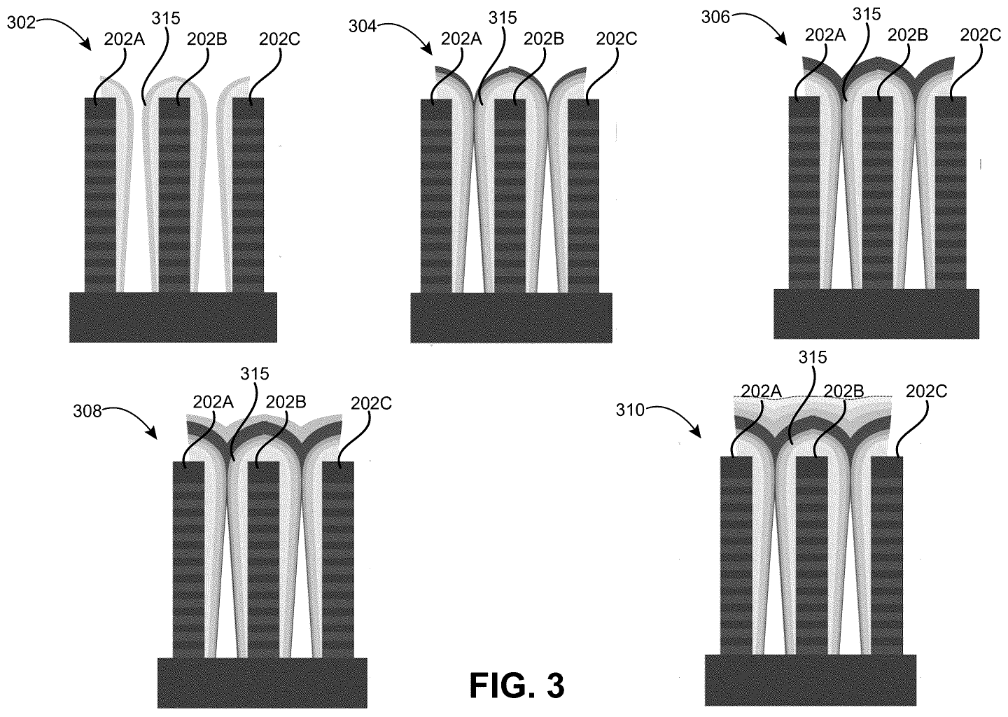

FIG. 3 shows schematics of multiple cross-sectional diagrams of a patterned sample during different portions of a gapfill deposition process, according to some embodiments. The pattern sample can be patterned sample 200 from FIG. 2. A first cross-sectional diagram 302 shows the patterned sample during an initial stage of the gapfill process. The patterned sample can include several pillars, such as pillar 202A, pillar 202B, or pillar 202C. Trenches can form on the patterned sample within spaces between pillars. For example, a trench can form between pillar 202A and pillar 202B or between pillar 202B and pillar 202C. The gapfill deposition process can involve filling the trenches with a gapfill material 315. Examples of the gapfill material 315 can include carbon, tungsten, amorphous silicon, etc. The patterned sample can be placed in a process chamber (e.g., process chamber 100 of FIG. 1), and the gapfill deposition process can be a PECVD deposition process.

During the initial stage of the gapfill process, the gapfill material 315 can accumulate within trenches and on top of pillars. The gapfill material 315 that forms above the pillars can be referred to as overgrowth. Deposition of the gapfill material 315 within the trenches can be described as sidewall growth or sidewall deposition. For example, in the first cross-sectional diagram 302, much of the gapfill material 315 shown in the trench between pillar 202A and pillar 202B is accumulating on the sides of the trench. Some of the gapfill material 315 is forming on the right side of pillar 202A and is growing towards the left side of pillar 202B. Additionally, some of the gapfill material 315 in the trench is forming on the left side of pillar 202B and growing towards the right side of pillar 202A. The initial stage of the gapfill deposition process can be described as a sidewall formation or a sidewall growth stage.

The second cross-sectional diagram 304 shows the patterned sample during a transition from an initial stage of the gapfill deposition process to a second stage of the gapfill deposition process. The second stage of the gapfill deposition process can be described as a pinch-off stage. The second cross-sectional diagram 304 can represent an onset of the pinch-off stage. Pinch-off can occur when a sidewall growth on one side of a trench contacts sidewall growth on another side (e.g., an opposite side) of the trench. The onset of the second stage can occur when at least one trench experiences pinch-off. Due to non-uniformity of the patterned sample or due to differing dimensions of trenches, trenches of the patterned sample can experience pinch-off at different times during the gapfill deposition process.

The third cross-sectional diagram 306 shows the patterned sample during the second stage or the pinchoff stage of the gapfill deposition process. During the pinchoff stage, a number of trenches that experience pinchoff accumulates. During this second stage, some trenches that experience pinchoff early on can accumulate additional overgrowth. The fourth cross-sectional diagram 308 shows the patterned sample during a transition from the second stage to a third stage of the gapfill deposition process. An onset of the third stage can occur once every (or almost every) trench experiences pinchoff. The third stage can be a stage where all trenches experience an accumulation of overgrowth. The fourth cross-sectional diagram 310 depicts the patterned sample during the third stage of the gapfill deposition process.

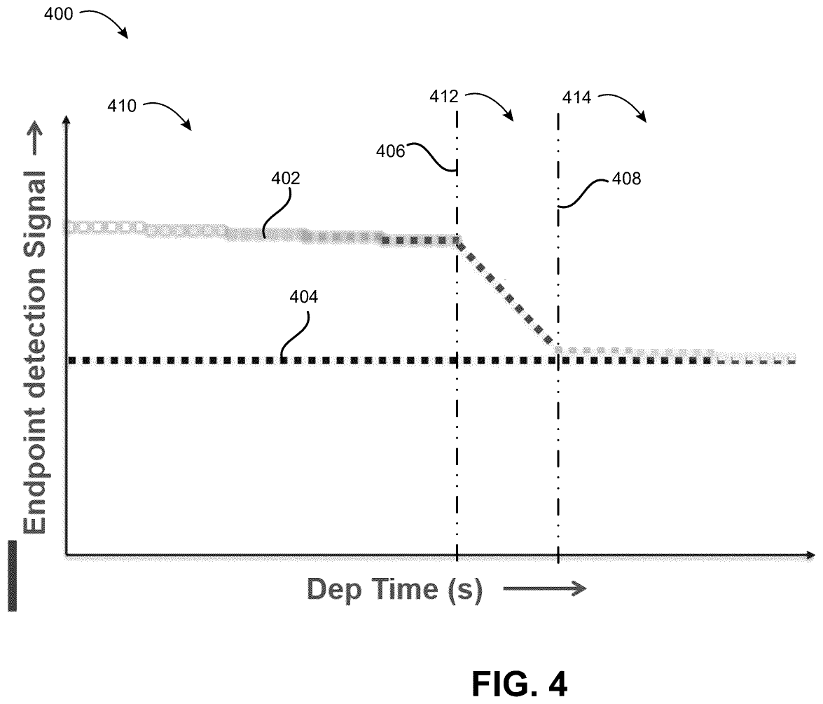

FIG. 4 is a graph 400 of a time-dependent characteristic of a plasma during a gapfill deposition process, according to some embodiments. The graph 400 can include two plots, a first plot 402 that represents characteristic of the plasma while filling trenches in a patterned sample with gapfill. For example, the characteristic of the plasma can be an impedance value of the plasma. The graph can also include a second plot 404 that represents a constant reference value of the characteristic of the plasma. The constant reference value can be associated with a characteristic of the plasma while in a presence of an unpatterned sample. The characteristic represented by the second plot 404 can be based on conditions present during the gapfill deposition process for the patterned sample.

The first plot 402 can indicate a time dependence of various stages of the gapfill deposition process. A first transition time 406 can indicate a time when a slope of the first plot 402 abruptly changes from a value of nearly zero to some nearly constant negative value. The first transition time 406 can indicate a transition from a first stage 410 of the gapfill process to a second stage 412 of the gapfill process. The first stage 410 can be associated with sidewall growth and can be evident in the first plot by a first time period before the first transition time. The second stage 412 of the gapfill process can be referred to as a pinch-off stage of the gapfill process. The second stage 412 can be associated with the region of the graph 400 when the first plot 402 experiences a nearly negative constant slope, a number of trenches of the patterned sample that experience pinchoff accumulates, and the characteristic of the plasma approaches the reference value of the second plot 404. A magnitude of the negative nearly constant slope can indicate a degree of uniformity of the patterned sample. The more uniform the patterned sample is, the steeper the negative constant slope can be. More uniform can mean less variation in width of trenches, height of trenches, or a combination of both dimensions. An endpoint for the second stage 412 can occur when all (or nearly all) of the trenches have experienced pinchoff.

A second transition time 408 can indicate a time when a slope of the first plot 402 abruptly changes from a nearly constant negative value to nearly zero. At the second transition time, the first plot 402 aligns with the second plot 404 and the characteristic of the plasma matches the reference value. The second transition time 408 can indicate an end of the pinch-off stage of the gapfill deposition process. The second transition time 408 can be detected from a comparison of a measured characteristic value (the value of the first plot 402) and the reference value from the second plot 404. If the comparison indicates that the two values match (within a predetermined factor of safety), then the end of the pinch-off phase can be detected. Once the pinch-off phase ends, a third phase of overgrowth accumulation for all trenches can begin. After a predetermined time after the second transition time has occurred, the process can be automatically ended.

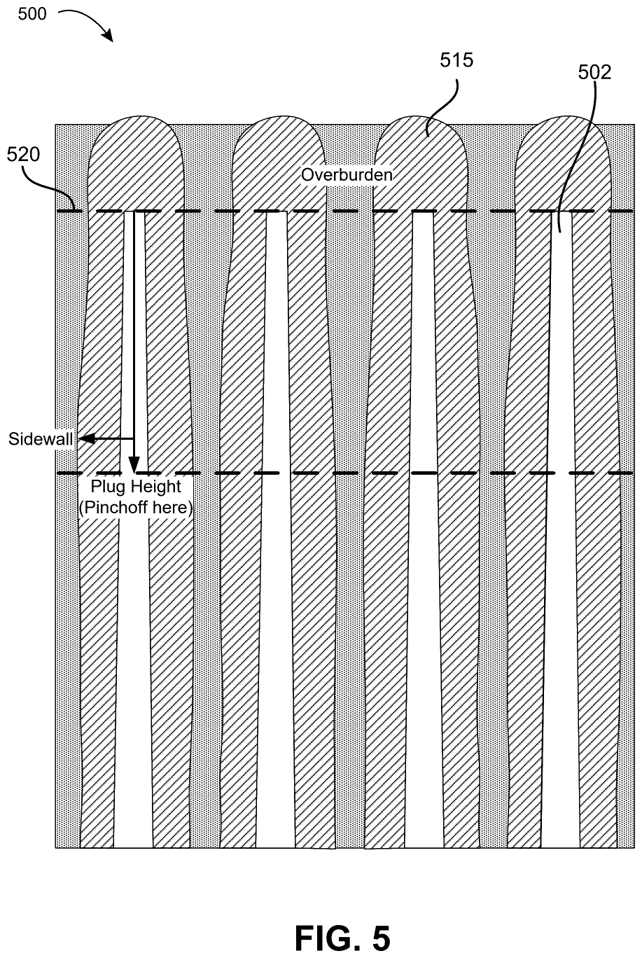

FIG. 5 is a cross-sectional transmission electron microscope (TEM) image 500 of a patterned sample with trenches partially filled with gapfill material 515, according to some embodiments. The TEM image 500 shows a snapshot of multiple pillars, including pillar 502, during a sidewall growth stage of a gapfill deposition process. Although several pillars are shown in FIG. 5, for simplicity, only pillar 502 is labeled. The sidewall growth stage can be evident in the TEM image 500 due to the lack of pinchoff. Sidewalls of each pillar do not appear to touch sidewalls of any other pillar in the TEM image 500.

The TEM image 500 also includes a boundary line 520. The boundary line 520 indicates a top boundary of each of the pillars. Any gapfill material 515 that accumulates above the boundary line 520 can be considered overburden. In the example shown in FIG. 5, widths of the pillars are about 50 nm, visible portions of heights of the pillars are roughly 700 nm, overburden height is about 100 nm, and trench widths are about 130 nm. In FIG. 5, sidewall growth appears to vary slightly by pillar and with depth and has a range of roughly 20-40 nm.

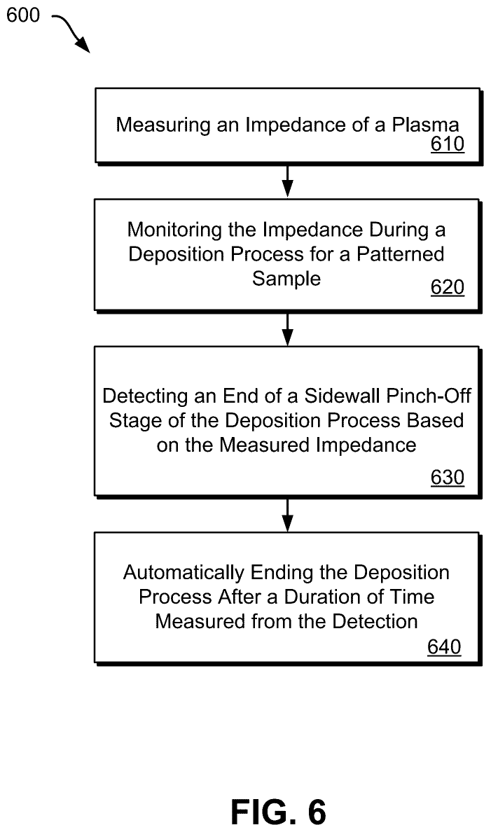

FIG. 6 is a flow chart of an example of a process 600 for detecting an end of a stage of a deposition process according to some aspects of the present disclosure. The operations of the flowchart start at block 610 and may be performed in the order indicated or in any suitable order. Other examples can involve more operations, fewer operations, different operations, or a different order of the operations shown in FIG. 6. Some or all of the steps of the process 600 can be performed by processors. Although for illustrative purposes, the process 600 is described relative to a deposition process, descriptions of the process 600 included in this disclosure can enable a person of ordinary skill in the art to apply the methods and systems to etching processes as well.

At block 610, the process 600 involves measuring a characteristic of a plasma. The plasma can be formed in a processing chamber such as processing chamber 100 described above. The characteristic of the plasma can be impedance of the plasma. The impedance can be a radio-frequency (RF) impedance that can be measured by at least one sensor in the processing chamber. The at least one sensor can include a matching circuit for determining the impedance of the plasma.

At block 620, the process 600 involves monitoring the impedance of the plasma during a deposition process for a patterned sample. The deposition process can be a backfill deposition process that involves depositing backfill material into trenches on the patterned sample. The trenches of the patterned sample can include different dimensions. For example, a first region of the patterned sample can include pillars with a width of 100 nm and a second region of the patterned sample can include pillars with a width of 200 nm. The backfill material can include carbon, tungsten, amorphous silicon, etc. Monitoring the impedance can involve creating a graph of impedance of the plasma versus time. A plot on the impedance versus time graph can behave similarly to plot 402 on graph 400 of FIG. 4. The plot can include regions of constant slope that can be associated with stages of the backfill deposition process. For example, a portion of the graph with a constant negative slope can be associated with a sidewall pinch-off stage of the backfill deposition process. A magnitude of the negative slope can be a measure of uniformity of the patterned sample. In some examples, the magnitude of the negative slope can be measured, and a sample patterning process can be altered based on the value of the measured slope.

At block 630, the process 600 involves detecting an end of a stage of the deposition process based on a condition, such as the measured impedance. The stage can be a sidewall pinch-off stage. The end of the sidewall pinch-off stage can be detected when the measured impedance of the plasma matches a reference value or reaches a threshold or change in slope. The reference value can be an impedance value associated with an unpatterned sample. For example, when the patterned sample has a substrate of silicon, the reference value can be determined using bare, unpatterned silicon. The reference value can be based on conditions associated with the deposition process. The conditions associated with the deposition process can include types of plasma gases, a flow rate of at least one of the gases, a co-flow rate of a plasma gas and a deposition precursor, temperature, precursors involved in the deposition process, at least one deposition rate, or at least one etch rate. In some examples, the end of the sidewall pinch-off stage can be detected based on a change in slope of a monitored graph of plasma impedance versus time.

At block 640, the process 600 involves performing an action such as automatically ending the deposition process after a duration of time measured from the detection of the end of the stage of the deposition process. The action can be performed in response to detecting the end of a stage of the deposition process. The stage can be a sidewall pinch-off stage. The duration of time can be a predetermined amount of time and can be based on a deposition rate for the backfill material or a target height for an overgrowth layer. An overgrowth layer can be a layer of backfill material that accumulates above tops of pillars of the patterned sample. The duration of time can be an amount of time that elapses before a smooth overgrowth layer is formed.

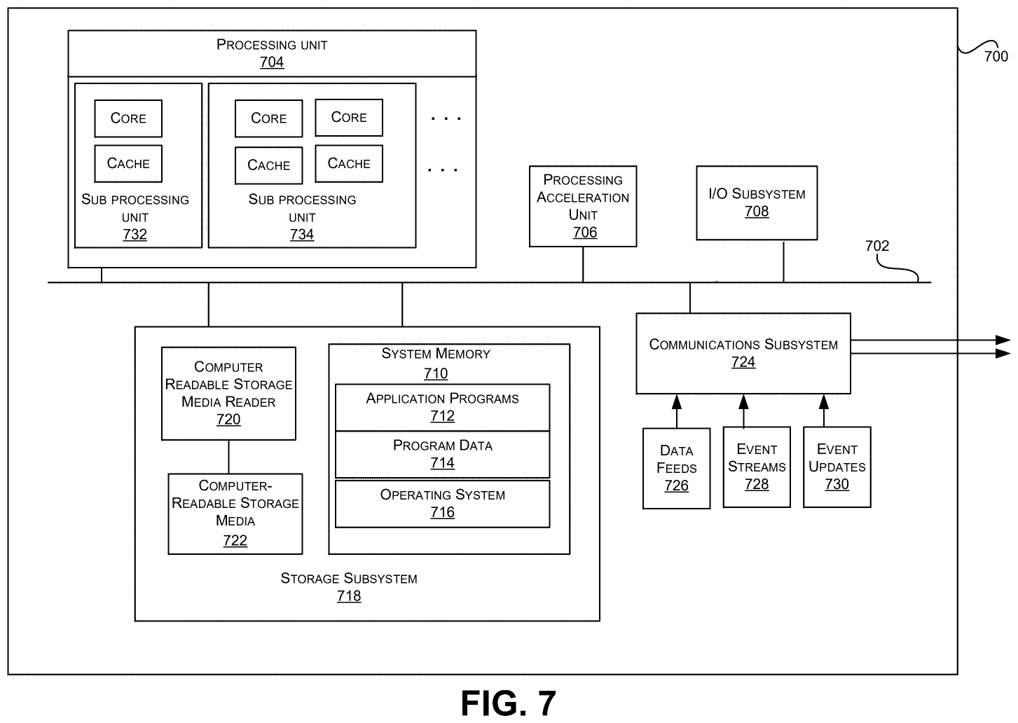

FIG. 7 illustrates an exemplary computer system 700, in which various embodiments may be implemented. The system 700 may be used to implement any of the computer systems described above. As shown in the figure, computer system 700 includes a processing unit 704 that communicates with a number of peripheral subsystems via a bus subsystem 702. These peripheral subsystems may include a processing acceleration unit 706, an I/O subsystem 708, a storage subsystem 718 and a communications subsystem 724. Storage subsystem 718 includes tangible computer-readable storage media 722 and a system memory 710.

Bus subsystem 702 provides a mechanism for letting the various components and subsystems of computer system 700 communicate with each other as intended. Although bus subsystem 702 is shown schematically as a single bus, alternative embodiments of the bus subsystem may utilize multiple buses. Bus subsystem 702 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, EtherCAT bus, and Peripheral Component Interconnect (PCI) bus, which can be implemented as a Mezzanine bus manufactured to the IEEE P1386.1 standard.

Processing unit 704, which can be implemented as one or more integrated circuits (e.g., a conventional microprocessor or microcontroller), controls the operation of computer system 700. One or more processors may be included in processing unit 704. These processors may include single core or multicore processors. In certain embodiments, processing unit 704 may be implemented as one or more independent processing units 732 and/or 734 with single or multicore processors included in each processing unit. In other embodiments, processing unit 704 may also be implemented as a quad-core processing unit formed by integrating two dual-core processors into a single chip.

In various embodiments, processing unit 704 can execute a variety of programs in response to program code and can maintain multiple concurrently executing programs or processes. At any given time, some or all of the program code to be executed can be resident in processor(s) 704 and/or in storage subsystem 718. Through suitable programming, processor(s) 704 can provide various functionalities described above. Computer system 700 may additionally include a processing acceleration unit 706, which can include a digital signal processor (DSP), a special-purpose processor, and/or the like.

I/O subsystem 708 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices.

User interface input devices may also include, without limitation, three dimensional (3D) mice, joysticks or pointing sticks, graphic tablets, and audio/visual devices such as speakers, digital cameras, digital camcorders, webcams, image scanners, fingerprint scanners, barcode reader 3D scanners, and/or laser rangefinders. User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 700 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 700 may comprise a storage subsystem 718 that comprises software elements, shown as being currently located within a system memory 710. System memory 710 may store program instructions that are loadable and executable on processing unit 704, as well as data generated during the execution of these programs.

Depending on the configuration and type of computer system 700, system memory 710 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 704. In some implementations, system memory 710 may include multiple different types of memory, such as static random access memory (SRAM) or dynamic random access memory (DRAM). In some implementations, a basic input/output system (BIOS), containing the basic routines that help to transfer information between elements within computer system 700, such as during start-up, may typically be stored in the ROM. By way of example, and not limitation, system memory 710 also illustrates application programs 712, which may include client applications, Web browsers, mid-tier applications, relational database management systems (RDBMS), etc., program data 714, and an operating system 716. By way of example, operating system 716 may include mobile operating systems for use on mobile devices.

Storage subsystem 718 may also provide a tangible computer-readable storage medium for storing the basic programming and data constructs that provide the functionality of some embodiments. Software (programs, code modules, instructions) that when executed by a processor provide the functionality described above may be stored in storage subsystem 718. These software modules or instructions may be executed by processing unit 704. Storage subsystem 718 may also provide a repository for storing data used in accordance with some embodiments.

Storage subsystem 700 may also include a computer-readable storage media reader 720 that can further be connected to computer-readable storage media 722. Together and, optionally, in combination with system memory 710, computer-readable storage media 722 may comprehensively represent remote, local, fixed, and/or removable storage devices plus storage media for temporarily and/or more permanently containing, storing, transmitting, and retrieving computer-readable information.

Computer-readable storage media 722 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 700.

By way of example, computer-readable storage media 722 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 722 may include, but is not limited to, flash memory cards, universal serial bus (USB) flash drives, secure digital (SD) cards, DVD disks, digital video tape, and the like. Computer-readable storage media 722 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 700.

Communications subsystem 724 provides an interface to other computer systems and networks. Communications subsystem 724 serves as an interface for receiving data from and transmitting data to other systems from computer system 700. For example, communications subsystem 724 may enable computer system 700 to connect to one or more devices via the Internet. In some embodiments communications subsystem 724 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 724 can provide wired network connectivity (e.g., Ethernet) in addition to or instead of a wireless interface.

Additionally, communications subsystem 724 may also be configured to receive data in the form of continuous data streams, which may include event streams 728 of real-time events and/or event updates 730, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 724 may also be configured to output the structured and/or unstructured data feeds 726, event streams 728, event updates 730, and the like to one or more databases that may be in communication with one or more streaming data source computers coupled to computer system 700.

Computer system 700 can be one of various types, including a handheld portable device (e.g., a smart phone, a computing tablet, etc.), a PC, a workstation, a mainframe, controller, a server rack, or any other data processing system.

Due to the ever-changing nature of computers and networks, the description of computer system 700 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method comprising:
measuring a characteristic of a plasma;
monitoring the characteristic of the plasma during a process involving the plasma;
detecting an end of a stage of the process based on a comparison of the measured characteristic to a reference value; and
performing at least one action in response to detecting the end of the stage of the process.

2. The method of claim 1, wherein the characteristic is an impedance of the plasma, wherein the process is a plasma-enhanced chemical vapor deposition (PECVD) gapfill deposition process for a patterned sample, the stage of the process is a sidewall pinch-off stage, and performing the at least one action comprises automatically ending the process after a duration of time measured from the detection.

3. The method of claim 2, wherein the patterned sample comprises a plurality of trenches, and at least one trench in the plurality of trenches includes a different dimension than a dimension of any other trench in the plurality of trenches.

4. The method of claim 2, wherein the gapfill deposition process comprises a deposition of gapfill material comprising carbon, tungsten, or amorphous silicon.

5. The method of claim 1, wherein the reference value is based on conditions associated with the process.

6. The method of claim 5, wherein the conditions associated with the process comprise types of plasma gases, a flow rate of at least one plasma gas, a temperature, precursors involved in the process, at least one deposition rate, or at least one etch rate.

7. The method of claim 1, further comprising:
measuring a slope of the characteristic over time for a portion of the process; and
altering at least one step in a sample patterning process based on the slope.

8. A system comprising:
a plasma system configured to perform deposition processes or etching processes;
at least one sensor configured to measure a characteristic of a plasma in the plasma system; and
a controller comprising:
one or more processors; and
one or more memory devices comprising instructions that are executable by the processor for causing the processor to perform operations comprising:
monitoring the characteristic during a process involving the plasma;
detecting an end of a stage of the process based on a comparison of the characteristic and a reference value; and
performing at least one action in response to detecting the end of the stage of the process.

9. The system of claim 8, wherein the characteristic comprises an impedance of the plasma, the process comprises a plasma-enhanced chemical vapor deposition (PECVD) gapfill deposition process for a patterned sample, the stage of the process is a sidewall pinch-off stage, and the operation of performing the at least one action comprises automatically ending the process after a duration of time measured from the detection.

10. The system of claim 9, wherein the patterned sample comprises a plurality of trenches, and at least one trench in the plurality of trenches includes a different dimension than a dimension of any other trench in the plurality of trenches.

11. The system of claim 9, wherein the gapfill deposition process comprises a deposition of gapfill material comprising carbon, tungsten, or amorphous silicon.

12. The system of claim 8, wherein the reference value is based on conditions associated with the process.

13. The system of claim 12, wherein the conditions associated with the process comprise types of plasma gases, a flow rate of at least one plasma gas, a temperature, precursors involved in the process, at least one deposition rate, or at least one etch rate.

14. The system of claim 8, wherein the operations further comprise:
measuring a slope of the characteristic over time for a portion of the process; and
altering at least one step in a sample patterning process based on the slope.

15. One or more non-transitory computer-readable media comprising instructions that, when executed by one or more processors, cause the one or more processors to perform operations comprising:
monitoring a measured characteristic of a plasma during a process involving the plasma;
detecting an end of a stage of the process based on a comparison of the measured characteristic to a reference value; and
performing at least one action in response to detecting the end of the stage of the process.

16. The one or more non-transitory computer-readable media of claim 15, wherein the measured characteristic comprises an impedance of the plasma, the process comprises a plasma-enhanced chemical vapor deposition (PECVD) gapfill deposition process for a patterned sample, the stage of the process comprises a sidewall pinch-off stage, and the operation of performing the at least one action comprises automatically ending the process after a duration of time measured from the detection.

17. The one or more non-transitory computer-readable media of claim 16, wherein the patterned sample comprises a plurality of trenches, and at least one trench in the plurality of trenches includes a different dimension than a dimension of any other trench in the plurality of trenches.

18. The one or more non-transitory computer-readable media of claim 16, wherein the gapfill deposition process comprises a deposition of gapfill material comprising carbon, tungsten, or amorphous silicon.

19. The one or more non-transitory computer-readable media of claim 15, wherein the reference value is based on conditions associated with the process.

20. The one or more non-transitory computer-readable media of claim 19, wherein the conditions associated with the process comprise types of plasma gases, flow rate of at least one plasma gas, temperature, precursors involved in the process, at least one deposition rate, or at least one etch rate.
